(19) United States
(12) Patent Application Publication
(10) Pub. No.: US 2026/0047510 A1
(43) Pub. Date: Feb. 12, 2026

(54) PICK AND PLACE FABRICATION USING THIN FILM COMPONENTS

(71) Applicant: BAE SYSTEMS Information and Electronic Systems Integration Inc., Nashua, NH (US)

(72) Inventors: Nathaniel P. Wyckoff, Marion, IA (US); Alexander S. Warren, North Liberty, IA (US); Benjamin Terry, Cedar Rapids, IA (US); Ryan Littler, Cedar Rapids, IA (US)

(73) Assignee: BAE SYSTEMS Information and Electronic Systems Integration Inc., Nashua, NH (US)

(21) Appl. No.: 18/799,374

(22) Filed: Aug. 9, 2024

(51) Int. Cl. H01L 23/498; H01L 21/60

(52) U.S. Cl. CPC H01L 23/49816; H01L 21/60; H01L 2021/6024

(57) ABSTRACT

Techniques are provided for fabrication of an electronic device. A methodology implementing the techniques according to an embodiment includes forming a plurality of thin film components on a wafer substrate. The method also includes cutting one or more of the thin film components from the wafer substrate and extracting the one or more of the thin film components from the wafer substrate. The method further includes depositing the extracted thin film components onto pads of a printed circuit board (PCB) assembly. The method further includes performing a solder reflow to electrically couple the one or more thin film components onto the pads of the PCB assembly. The thin film component comprises a release layer, solder layers, solder barrier layers, non-wetting solder barrier layers, a passivation layer, and a component function layer. The component function layer may provide a resistive function, a capacitive function, a diode function, or a thermocouple function.

### FIELD OF DISCLOSURE

The present disclosure relates to electronic device, and more particularly to pick and place fabrication of thin film components for electronic devices.

### BACKGROUND

Surface mounted components can consume large areas of a circuit board assembly, increasing the size, weight, and cost of electronic devices. Additionally, the surface mounting process can be time consuming, which slows down circuit board fabrication and packaging operations.

### BRIEF DESCRIPTION OF THE DRAWINGS

FIG. 1 illustrates thin film component fabrication, in accordance with certain embodiments of the present disclosure.

FIG. 2 illustrates a pick and place process for thin film components, in accordance with certain embodiments of the present disclosure.

FIG. 3 is a cross sectional view of a thin film capacitor, configured in accordance with certain embodiments of the present disclosure.

FIG. 4A is a cross sectional view of a thin film resistor, configured in accordance with certain embodiments of the present disclosure.

FIG. 4B is a cross sectional view of a tuned resistor layer, configured in accordance with certain embodiments of the present disclosure.

FIG. 5 is a cross sectional view of a thin film diode, configured in accordance with certain embodiments of the present disclosure.

FIG. 6 is a cross sectional view of a thin film thermocouple, configured in accordance with certain embodiments of the present disclosure.

FIG. 7 illustrates cross sectional views of thin film component application to a printed circuit board (PCB), in accordance with certain embodiments of the present disclosure.

FIG. 8 is a flowchart illustrating a methodology for fabrication of an electronic device using a pick and place operation on thin film components, in accordance with an embodiment of the present disclosure.

Although the following Detailed Description will proceed with reference being made to illustrative embodiments, many alternatives, modifications, and variations thereof will be apparent in light of this disclosure.

### DETAILED DESCRIPTION

Techniques are provided herein for pick and place fabrication of thin film components for microelectronic devices such as printed circuit boards (PCBs) or circuit card assemblies (CCAs), ball grid arrays (BGAs) and die pads. As noted above, surface mounted components can consume large areas of a PCB, increasing the size, weight, and cost of electronic devices employing those circuit boards. Additionally, the surface mounting process can be time consuming, which slows down circuit board fabrication and packaging operations.

To this end, and in accordance with an embodiment of the present disclosure, thin film components may be prefabricated on a wafer substrate in relatively large numbers (e.g., hundreds, thousands, or tens of thousands), and subsequently picked and placed onto a microelectronic device (e.g., a circuit board), as needed to manufacture a given circuit design. The thin film components, prefabricated in this manner, can be significantly smaller and less expensive than traditional surface mount components. Prefabrication of the components also allows for faster manufacture. The thin film components may include, for example, passive components such as resistors, capacitors, and thermocouples, and active components such as diodes, although other component types are possible. Additionally, the components may be pre-tested which allows for selection of components having characteristic values (e.g., resistance, capacitance, break down voltage, etc.) that more precisely match the required values.

In accordance with an embodiment, a methodology implementing the techniques for pick and place fabrication of thin film components includes forming a plurality of thin film components on a wafer substrate, cutting (e.g., dicing) one or more of the thin film components from the wafer substrate, and extracting the one or more of the thin film components from the wafer substrate. The method further includes depositing the one or more thin film components onto pads of a PCB assembly. The method further includes performing a solder reflow to electrically couple the one or more thin film components onto the pads of the PCB assembly. The thin film component comprises a release layer, solder layers, solder barrier layers, non-wetting solder barrier layers, a passivation layer, and a component function layer, as will be described in greater detail below. In some embodiments, the component function layer may provide a resistive function, a capacitive function, a diode function, or a thermocouple function.

It will be appreciated that the thin film fabrication techniques described herein may provide for improved circuit board assembly, resulting in electronic devices of smaller size and weight, at reduced cost, compared to other methods that use surface mounted components. Numerous embodiments and applications will be apparent in light of this disclosure.

### Thin Film Components

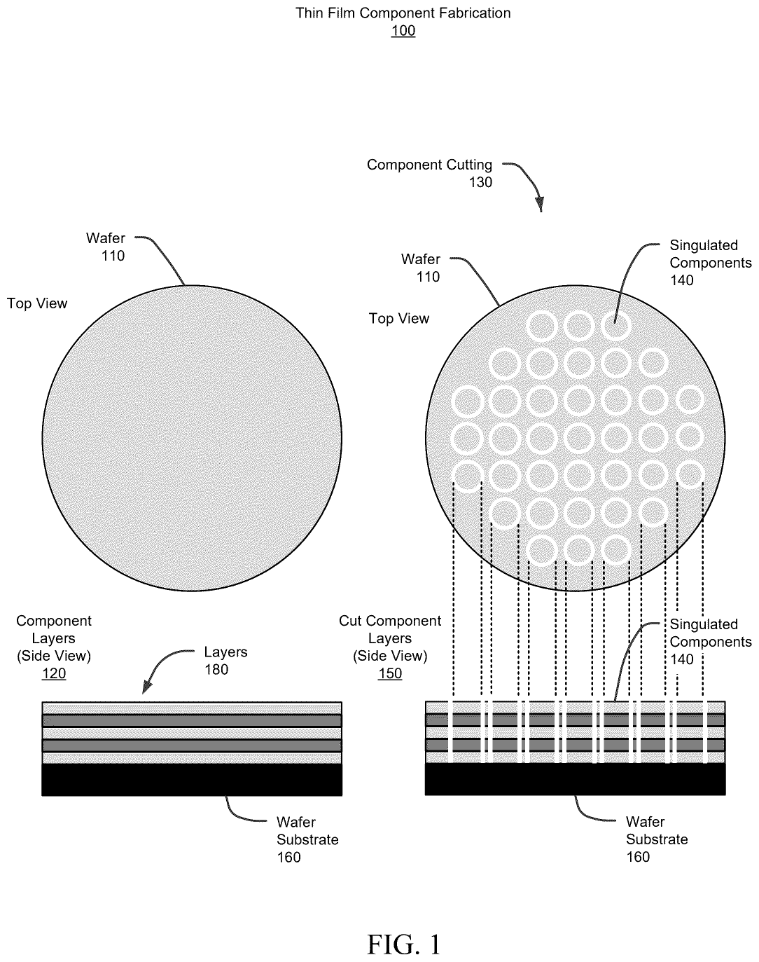

FIG. 1 illustrates thin film component fabrication 100, in accordance with certain embodiments of the present disclosure. The fabrication of thin film components on a wafer 110 involves building up a number of layers of material on a substrate, for example using a vapor deposition process or other suitable means including electroforming. A side view 120 of the layers of the thin film component illustrates a cross section of the wafer 110 showing the wafer substrate 160 and the various layers 180 disposed on the substrate. The composition and arrangement of the layers 180 will be described in greater detail below.

After the layers are formed on the wafer, individual thin film components are cut from the wafer as illustrated at 130. In some embodiments, the cutting process employs a laser to cut around the circumference of each component. The top view shows the cut, or singulated, components 140. The side view 150 illustrates how the cutting extends from the top layer down through the bottom layer, stopping at the substrate 160. In some embodiments, the bottom layer is a release layer configured to facilitate extraction of the singulated components 140 from the substrate 160, as will be described below.

In some embodiments, the wafer 110 may be sized to a diameter in the range of 7 inches to 9 inches and the number of singulated components 140 may be in the range of 80000 to 90000 components.

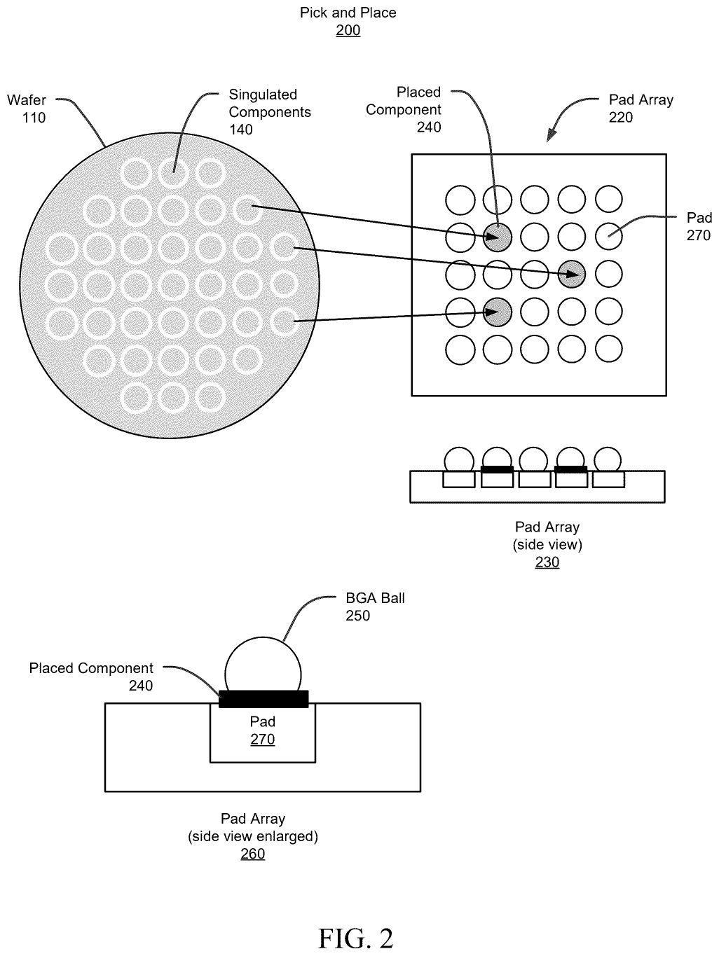

FIG. 2 illustrates a pick and place process 200 for thin film components, in accordance with certain embodiments of the present disclosure. During the pick and place process 200, singulated components 140 are picked up from the wafer 110. In some embodiments, the singulated components are extracted from the wafer substrate using a vacuum tool. The extracted components are then placed 240 on pads 270 of a pad array 220. A side view 230 of the pad array is illustrated along with an enlarged view 260 of one of the pads 270. The enlarged view 260 shows one of the placed components 240 disposed between the pad 270 and the ball 250 of a BGA that is subsequently soldered to the pad array.

In some embodiments, the singulated components 140 may be pre-tested to allow for selection of components that exhibit characteristic values (e.g., resistance, capacitance, break down voltage, etc.) that meet specified requirements.

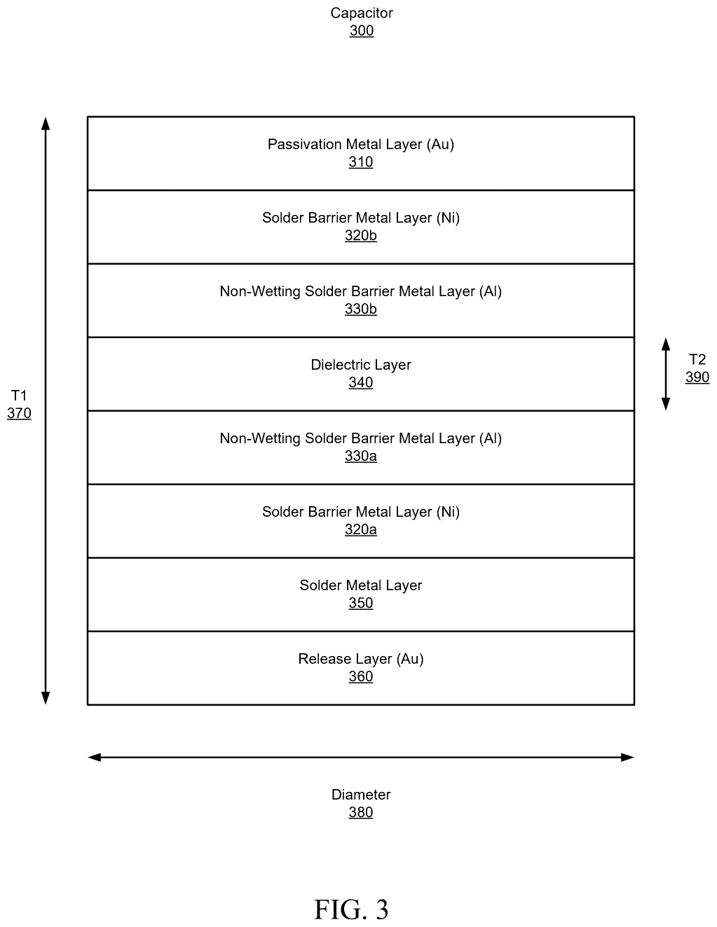

FIG. 3 is a cross sectional view of a thin film capacitor 300, configured in accordance with certain embodiments of the present disclosure. The thin film capacitor 300 is shown to include a passivation metal layer 310, two solder barrier metal layers 320a and 320b, two non-wetting solder barrier metal layers 330a and 330b, a dielectric layer 340, a solder metal layer 350, and a release layer 360.

The term “solder,” as used herein, refers to reflowable conductive material that may be used to create a bond between components or portions of components, and may comprise any suitable elements, unless otherwise stated.

Describing the layers from bottom to top, the release layer 360 is configured to facilitate release of the thin film component 300 from the wafer substrate 160 on which the thin film component is formed. In some embodiments, the release layer 360 comprises gold. Gold is a noble metal which does not form strong bonds to most materials. When deposited on a glass or silicon wafer it bonds weakly and separates when mechanically stressed (e.g., the during pick and place operation). An additional advantage of gold is that it passivates solder to prevent it from oxidizing, and it is consumed by the solder during reflow. In some embodiments, materials other than gold may be used.

The solder metal layer 350 is disposed on the release layer 360 and is configured to provide solder for a solder reflow connection that is used to attach the thin film component to a device pad (e.g., a pad of the PCB). In some embodiments, the solder metal layer 350 may also act as the release layer.

The first solder barrier metal layer 320a is disposed on the solder metal layer 350 and is configured to bond to the solder to protect the thin film component during the solder reflow. In some embodiments, the first solder barrier metal layer 320a comprises nickel.

The first non-wetting solder barrier metal layer 330a is disposed on the first solder barrier metal layer 320a and is configured to inhibit wicking of the solder around edges of the thin film component during the solder reflow which could circuit the device. In some embodiments, the first non-wetting solder barrier metal layer 330a comprises aluminum.

The dielectric layer 340 is disposed on the first non-wetting solder barrier metal layer 330a and is configured to perform an electrical function of the thin film component. In this case, the component function layer comprises a dielectric material 440 which is configured to provide a desired capacitance. In some embodiments, the dielectric material 440 may have a dielectric constant in the range of 2 to 1000 and may provide a capacitance in the range of 3 picofarads (pF) to 140 nanofarads (nF). In some embodiments, the dielectric material may comprise silica, alumina, titania, or barium titanate.

The second non-wetting solder barrier metal layer 330b is disposed on the dielectric layer 340 and is configured to inhibit wicking of the solder around the edges of the thin film component during the solder reflow. In some embodiments, the second non-wetting solder barrier metal layer 330b comprises aluminum.

The second solder barrier metal layer 320b is disposed on the second non-wetting solder barrier metal layer and is configured to bond to the solder to protect the thin film component during the solder reflow. In some embodiments, the second solder barrier metal layer 320b comprises nickel.

The passivation metal layer 310 is disposed on the second solder barrier metal layer 320b and is configured to be consumed during soldering to protect the second solder barrier metal layer. In some embodiments, the passivation metal layer 310 is a non-oxidizing metal layer. In some embodiments, the passivation metal layer 310 comprises gold, although other materials may be used.

In some embodiments, the thickness T1 370 of the thin film component 300 may be in the range of 5 micrometers (um) to 20 um. For example, the thickness 370 may be approximately 5 um for a Flip Chip application or approximately 20 um for a BGA application.

In some embodiments, the thickness of an individual layer T2 390 of the thin film component 300 may be in the range of 50 nanometers (nm) to 10 um.

In some embodiments, the thin film component 300 is cylindrical with a diameter 380 in the range of 50 um to 1000 um. For example, the diameter 380 may be approximately 50 um to 150 um for a Flip Chip application or approximately 500 um to 1000 um for a BGA application. In some embodiments, the pads may be shapes other than cylindrical, for example, square or hexagonal, with a cross sectional dimension comparable to the diameter of the cylindrical pads described above.

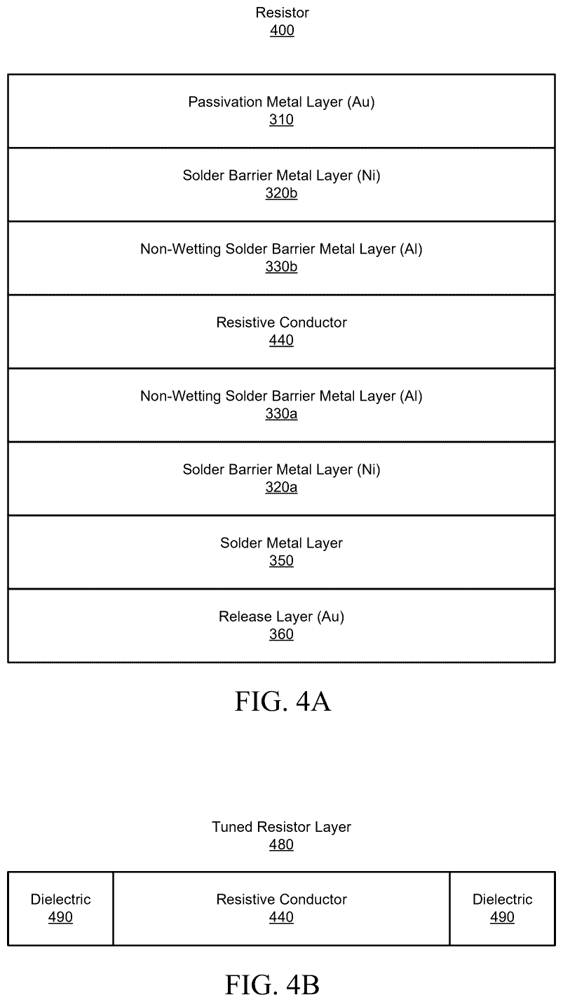

FIG. 4A is a cross sectional view of a thin film resistor 400, configured in accordance with certain embodiments of the present disclosure. The thin film resistor 400 is shown to include a passivation metal layer 310, two solder barrier metal layers 320a and 320b, two non-wetting solder barrier metal layers 330a and 330b, a resistive conductor layer 440, a solder metal layer 350, and a release layer 360.

The Layers of the thin film resistor 400 are substantially the same (e.g., in composition, placement, and dimension) as the layers of the thin film capacitor 300 described above, with the exception of the component function layer. In this case, the component function layer comprises a resistive conductor material 440 which is configured to provide a desired electrical resistance. In some embodiments, the resistance may be in the range of less than one ohm to teraohms. In some embodiments, resistive conductor material 440 may comprise titanium nitride, nickel chromium, silica, nickel oxide, silicon, or a silicon nickel oxide mixture. More complex geometries are also possible. For example, in some embodiments, the resistance can be tuned by adding a dielectric material 490 to the resistor layer 440 to reduce the effective area of the resistive conductor thereby changing the resistance value, as shown in FIG. 4B.

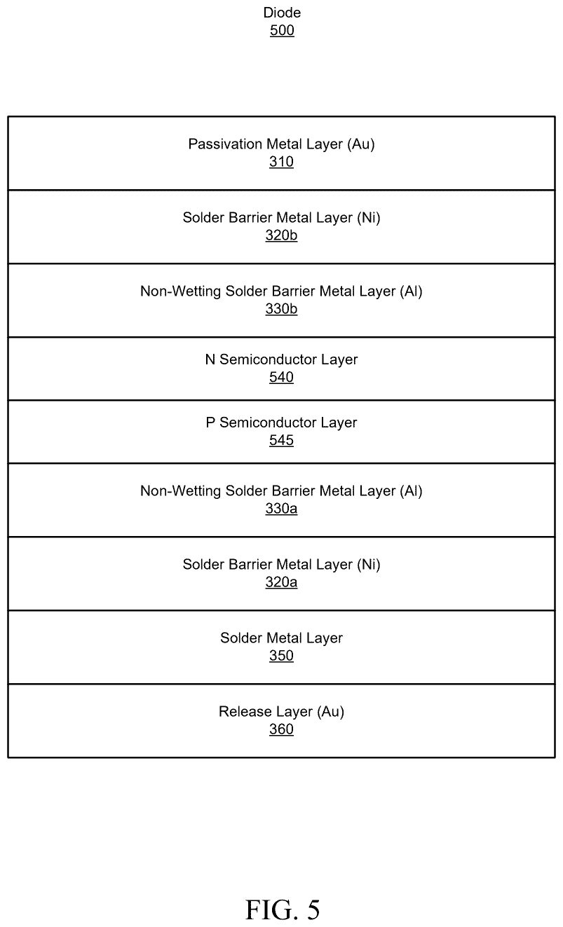

FIG. 5 is a cross sectional view of a thin film diode 500, configured in accordance with certain embodiments of the present disclosure. The thin film diode 500 is shown to include a passivation metal layer 310, two solder barrier metal layers 320a and 320b, two non-wetting solder barrier metal layers 330a and 330b, an N-type semiconductor layer 540, a P-type semiconductor layer 545, a solder metal layer 350, and a release layer 360.

The Layers of the thin film diode 500 are substantially the same (e.g., in composition, placement, and dimension) as the layers of the thin film capacitor 300 described above, with the exception of the component function layer. In this case, the component function layer comprises an N-type semiconductor material 540 disposed on a P-type semiconductor material 545 which are configured to provide the functionality of a diode. In some embodiments, the P-type semiconductor material may comprise P-type silicon, P-type gallium nitride, aluminum, or P-type gallium arsenide. In some embodiments, the N-type semiconductor material may comprise N-type silicon, N-type gallium nitride, or N-type gallium arsenide.

In some embodiments, the diode may be a Schottky diode, wherein only one of the semiconductor layers (e.g., either the N-type layer or the P-type layer, although typically the N-type later) is present and the other semiconductor layer is replaced by a metal. In some embodiment, the metal may molybdenum, platinum, chromium, or tungsten.

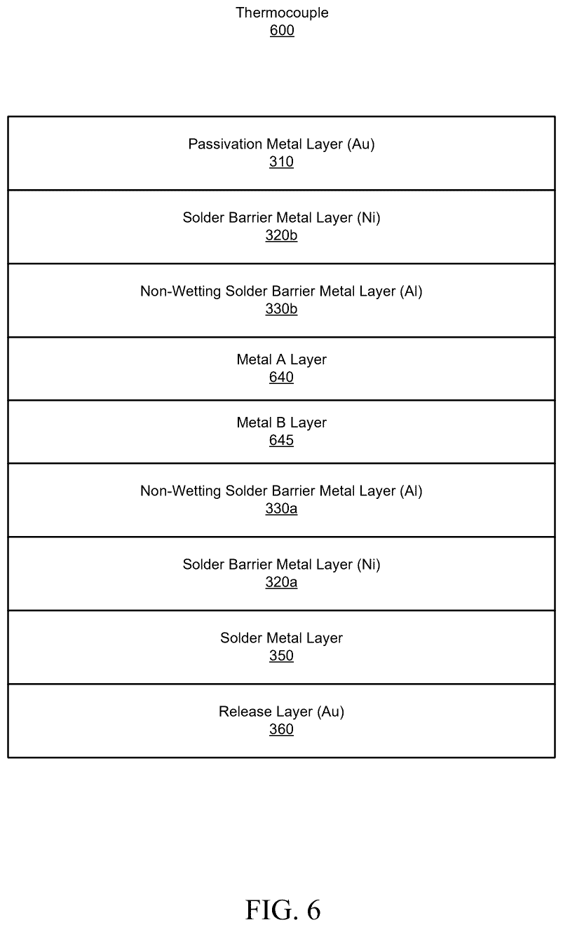

FIG. 6 is a cross sectional view of a thin film thermocouple 600, configured in accordance with certain embodiments of the present disclosure. The thin film thermocouple 600 is shown to include a passivation metal layer 310, two solder barrier metal layers 320a and 320b, two non-wetting solder barrier metal layers 330a and 330b, an first metal layer (metal layer A) 640, a second metal layer (metal layer B) 645, a solder metal layer 350, and a release layer 360.

The Layers of the thin film thermocouple 600 are substantially the same (e.g., in composition, placement, and dimension) as the layers of the thin film capacitor 300 described above, with the exception of the component function layer. In this case, the component function layer comprises a first metal layer 640 disposed on a second metal layer 645 which are configured to provide the functionality of a thermocouple. In some embodiments, a type T thermocouple may be fabricated in which the first metal layer comprises copper and the second metal layer comprises constantan. In some embodiments, a type J thermocouple may be fabricated in which the first metal layer comprises iron and the second metal layer comprises constantan. In some embodiments, a type K thermocouple may be fabricated in which the first metal layer comprises nickel-chromium and the second metal layer comprises nickel-aluminum. In some embodiments, a type S thermocouple may be fabricated in which the first metal layer comprises platinum-rhodium (at 10% rhodium) and the second metal layer comprises platinum. In some embodiments, any two dissimilar materials may be used to fabricate a thermocouple having desired properties.

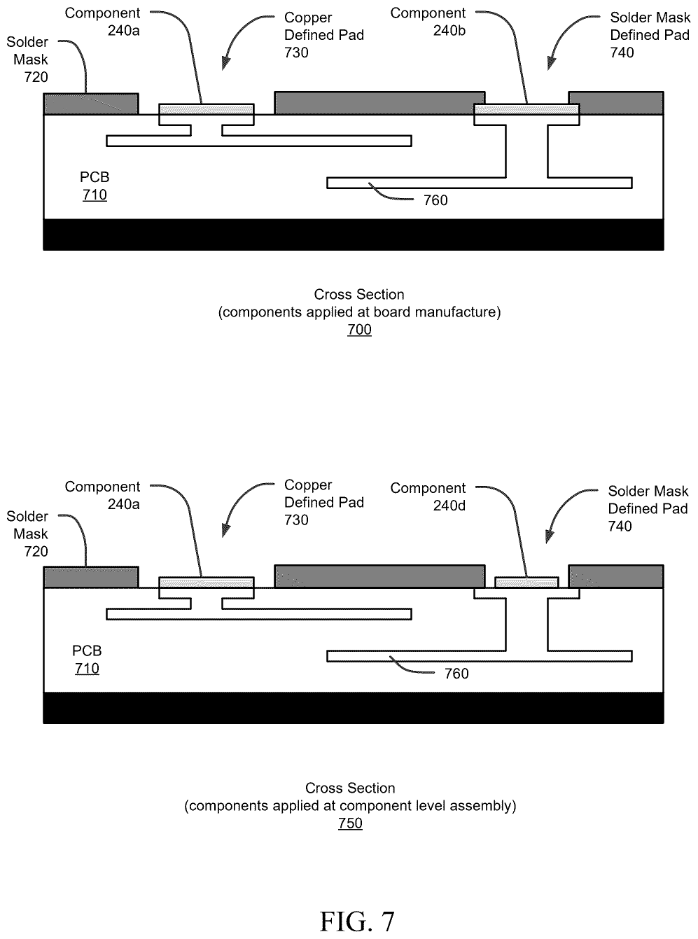

FIG. 7 illustrates cross sectional views 700 and 750 of thin film component application to a PCB 710, in accordance with certain embodiments of the present disclosure. The cross sectional views 700 and 750 show a PCB 710 which includes embedded layers of conductive routes 760 that provide electrical coupling between components.

The first cross sectional view 700 illustrates a case where the thin film components 240 are applied at the PCB manufacturing stage. Components 240 may be deposited onto a copper defined pad, or a solder mask defined pad. For example, component 240a is shown to be deposited onto a copper defined pad 730 while component 240b is shown to be deposited onto a solder mask defined pad 740. An examination of the cross-section shows that the component 240b extends underneath the solder mask, when the component is deposited onto a solder mask defined pad 740 during PCB manufacture.

The second cross sectional view 750 illustrates a case where the thin film components 240 are applied during component level assembly (e.g., after the PCB has been manufactured). Components 240 may again be deposited onto a copper defined pad, or a solder mask defined pad. For example, component 240a is shown to be deposited onto a copper defined pad 730 while component 240d is shown to be deposited onto a solder mask defined pad 740. An examination of the cross-section shows that the component 240d lies on top of the pad and does not extend underneath the solder mask, when the component is deposited onto a solder mask defined pad 740 after PCB manufacture. This is different from the case 700 described above, where the thin film components 240 are applied at the PCB manufacturing stage.

### Methodology

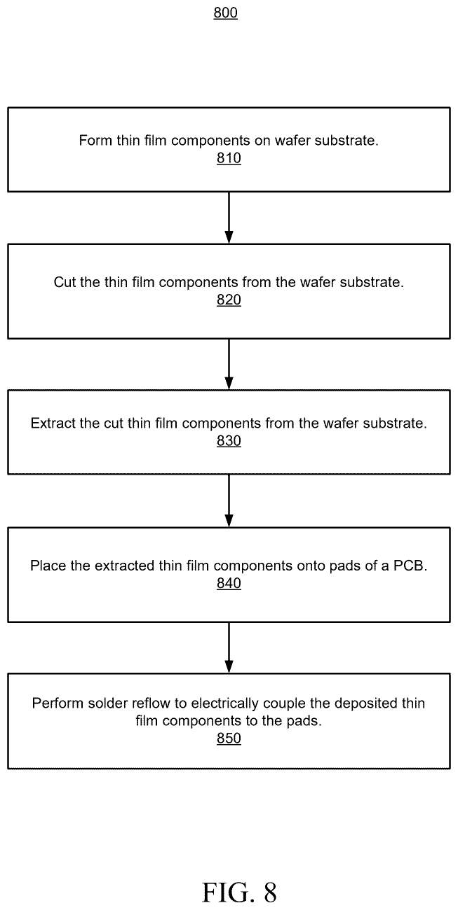

FIG. 8 is a flowchart illustrating a methodology 800 for fabrication of an electronic device using a pick and place operation on thin film components, in accordance with an embodiment of the present disclosure. As can be seen, example method 800 includes a number of phases and sub-processes, the sequence of which may vary from one embodiment to another. However, when considered in aggregate, these phases and sub-processes form a process for fabrication of an electronic device using a pick and place operation on thin film components, in accordance with certain of the embodiments disclosed herein, for example as illustrated in FIGS. 1-7, as described above. However other system architectures can be used in other embodiments, as will be apparent in light of this disclosure. To this end, the correlation of the various functions shown in FIG. 8 to the specific components illustrated in the figures, is not intended to imply any structural and/or use limitations. Rather other embodiments may include, for example, varying degrees of integration wherein multiple functionalities are effectively performed by one system. Numerous variations and alternative configurations will be apparent in light of this disclosure.

In one embodiment, method 800 commences, at operation 810, by forming a plurality of thin film components on a wafer substrate. The think film components may comprise a number of layers, including, for example, a release layer, to facilitate the pick and place operation, as previously described. Additionally, at least one of the layers may include a layer configured to provide a desired electrical function such as, for example, capacitance, resistance, diode, and thermocouple functionality, as previously described. In some embodiments, the thin film components are formed using a vapor deposition process, although other suitable processes may be used.

At operation 820, one or more of the thin film components are cut from the wafer substrate. In some embodiments, the cutting process employs a laser to cut around the circumference of the component so that the component is only held to the wafer substrate by the release layer.

At operation 830, the one or more cut thin film components are picked up or extracted from the wafer substrate. In some embodiments, the thin film components are extracted from the wafer substrate using a vacuum tool.

At operation 840, the one or more extracted thin film components are placed or deposited onto pads of a PCB, circuit board, or circuit card assembly.

At operation 850, a solder reflow is performed to electrically couple the one or more deposited thin film components to the pads of the PCB or circuit board assembly.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smartphones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood, however, that other embodiments may be practiced without these specific details, or otherwise with a different set of details. It will be further appreciated that the specific structural and functional details disclosed herein are representative of example embodiments and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

Example 1 is a thin film component comprising: a release layer configured to provide release of the thin film component from a substrate on which the thin film component is formed; a solder metal layer disposed on the release layer and configured to provide solder for a solder reflow connection to a device pad; a first solder barrier metal layer disposed on the solder metal layer and configured to bond to the solder to protect the thin film component during the solder reflow; a first non-wetting solder barrier metal layer disposed on the first solder barrier metal layer and configured to inhibit wicking of the solder around edges of the thin film component during the solder reflow; a component function layer disposed on the first non-wetting solder barrier metal layer and configured to perform an electrical function of the thin film component; and a passivation metal layer configured to be consumed during soldering to protect the second solder barrier metal layer.

Example 2 includes the system of Example 1, further comprising: a second non-wetting solder barrier metal layer disposed on the component function layer and configured to inhibit wicking of the solder around the edges of the thin film component during the solder reflow; a second solder barrier metal layer disposed on the second non-wetting solder barrier metal layer and configured to bond to the solder to protect the thin film component during the solder reflow; and the passivation metal layer is a non-oxidizing metal layer disposed on the second solder barrier metal layer.

Example 3 includes the system of Examples 1 or 2, wherein the electrical function is a capacitor, and the component function layer is a dielectric.

Example 4 includes the system of any of Examples 1 or 2, wherein the electrical function is a resistor, and the component function layer is a resistive conductor.

Example 5 includes the system of any of Examples 1 or 2, wherein the electrical function is a diode, and the component function layer comprises an N-type semiconductor layer disposed on a P-type semiconductor layer.

Example 6 includes the system of any of Examples 1 or 2, wherein the electrical function is a thermocouple, and the component function layer comprises a first metal layer disposed on a second metal layer.

Example 7 includes the system of any of Examples 1-6, wherein the release layer and the passivation metal layer comprise gold, the first and second solder barrier metal layers comprise nickel, and the first and second non-wetting solder barrier metal layers comprise aluminum.

Example 8 includes the system of any of Examples 1-7, wherein the thin film component is of a thickness in the range of 5 micrometers (um) to 20 um and a cross sectional dimension in the range of 50 um to 1000 um.

Example 9 is a method for fabricating an electronic device, the method comprising: forming a plurality of thin film components on a wafer substrate; cutting one or more of the thin film components from the wafer substrate; extracting the one or more cut thin film components from the wafer substrate; depositing the one or more extracted thin film components onto pads of a printed circuit board (PCB) assembly; and performing a conductor reflow to electrically couple the one or more deposited thin film components to the pads of the PCB assembly.

Example 10 includes the method of Example 9, wherein the thin film component comprises: a release layer configured to provide release of the thin film component from the wafer substrate; a layer of reflowable conductive material disposed on the release layer and configured to provide conductive material for the conductor reflow coupling to the PCB pad; a first barrier metal layer disposed on the reflowable conductive material layer and configured to bond to the reflowable conductive material to protect the thin film component during the conductive material reflow; a first non-wetting barrier metal layer disposed on the first barrier metal layer and configured to inhibit wicking of the reflowable conductive material around edges of the thin film component during the conductive material reflow; a component function layer disposed on the first non-wetting barrier metal layer and configured to perform an electrical function of the thin film component; a second non-wetting barrier metal layer disposed on the component function layer and configured to inhibit wicking of the reflowable conductive material around the edges of the thin film component during the conductive material reflow; a second barrier metal layer disposed on the second non-wetting barrier metal layer and configured to bond to the reflowable conductive material to protect the thin film component during the conductive material reflow; and a passivation metal layer disposed on the second barrier metal layer and configured to be consumed during the conductor reflow to protect the second barrier metal layer.

Example 11 includes the method of Example 10, wherein the electrical function is a capacitor, and the component function layer is a dielectric.

Example 12 includes the method of Example 10, wherein the electrical function is a resistor, and the component function layer is a resistive conductor.

Example 13 includes the method of Example 10, wherein the electrical function is a diode, and the component function layer comprises an N-type semiconductor layer disposed on a P-type semiconductor layer.

Example 14 includes the method of Example 10, wherein the electrical function is a thermocouple, and the component function layer comprises a first metal layer disposed on a second metal layer.

Example 15 includes the method of any of Examples 10-14, wherein the release layer and the passivation metal layer comprise gold, the first and second barrier metal layers comprise nickel, and the first and second non-wetting barrier metal layers comprise aluminum.

Example 16 includes the method of any of Examples 9-14, wherein the thin film component is of a thickness in the range of 5 micrometers (um) to 20 um and a cross sectional dimension in the range of 50 um to 1000 um, the wafer substrate is cylindrical with a diameter in the range of 7 inches to 9 inches, and the plurality of thin film components comprises 80000 to 90000 thin film components.

Example 17 includes the method of any of Examples 9-14, wherein the forming of the plurality of thin film components on the wafer substrate comprises performing a vapor deposition process and the cutting of the one or more of the thin film components from the wafer substrate comprises employing a laser to perform the cutting.

Example 18 is an electronic device comprising: a printed circuit board (PCB) assembly comprising one or more solder pads; one or more thin film components comprising a first side and a second side, the second side opposite the first side, wherein the first side of the thin film components are soldered to the solder pads of the PCB assembly; and a circuit module comprising a ball grid array wherein the balls of the ball grid array are soldered to the second sides of the thin film components.

Example 19 includes the electronic device of Example 18, wherein the thin film component comprises: a release layer configured to provide release of the thin film component from a wafer substrate on which the thin film component was formed; a solder metal layer disposed on the release layer and configured to provide solder for a solder reflow connection to the solder pads of the PCB assembly; a first solder barrier metal layer disposed on the solder metal layer and configured to bond to the solder to protect the thin film component during the solder reflow; a first non-wetting solder barrier metal layer disposed on the first solder barrier metal layer and configured to inhibit wicking of the solder around edges of the thin film component during the solder reflow; a component function layer disposed on the first non-wetting solder barrier metal layer and configured to perform an electrical function of the thin film component; a second non-wetting solder barrier metal layer disposed on the component function layer and configured to inhibit wicking of the solder around the edges of the thin film component during the solder reflow; a second solder barrier metal layer disposed on the second non-wetting solder barrier metal layer and configured to bond to the solder to protect the thin film component during the solder reflow; and a passivation metal layer disposed on the second solder barrier metal layer and configured to be consumed during soldering to protect the second solder barrier metal layer.

Example 20 includes the electronic device of Example 19, wherein the electrical function is a capacitor, and the component function layer is a dielectric, or the electrical function is a resistor, and the component function layer is a resistive conductor, or the electrical function is a diode, and the component function layer comprises an N-type semiconductor layer disposed on a P-type semiconductor layer, or the electrical function is a thermocouple, and the component function layer comprises a first metal layer disposed on a second metal layer.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A thin film component comprising:
a release layer configured to provide release of the thin film component from a substrate on which the thin film component is formed;
a solder metal layer disposed on the release layer and configured to provide solder for a solder reflow connection to a device pad;
a first solder barrier metal layer disposed on the solder metal layer and configured to bond to the solder to protect the thin film component during the solder reflow;
a first non-wetting solder barrier metal layer disposed on the first solder barrier metal layer and configured to inhibit wicking of the solder around edges of the thin film component during the solder reflow;
a component function layer disposed on the first non-wetting solder barrier metal layer and configured to perform an electrical function of the thin film component; and
a passivation metal layer configured to be consumed during soldering to protect the second solder barrier metal layer.

2. The thin film component of claim 1, further comprising:
a second non-wetting solder barrier metal layer disposed on the component function layer and configured to inhibit wicking of the solder around the edges of the thin film component during the solder reflow;
a second solder barrier metal layer disposed on the second non-wetting solder barrier metal layer and configured to bond to the solder to protect the thin film component during the solder reflow; and
the passivation metal layer is a non-oxidizing metal layer disposed on the second solder barrier metal layer.

3. The thin film component of claim 1, wherein the electrical function is a capacitor, and the component function layer is a dielectric.

4. The thin film component of claim 1, wherein the electrical function is a resistor, and the component function layer is a resistive conductor.

5. The thin film component of claim 1, wherein the electrical function is a diode, and the component function layer comprises an N-type semiconductor layer disposed on a P-type semiconductor layer.

6. The thin film component of claim 1, wherein the electrical function is a thermocouple, and the component function layer comprises a first metal layer disposed on a second metal layer.

7. The thin film component of claim 1, wherein the release layer and the passivation metal layer comprise gold, the first and second solder barrier metal layers comprise nickel, and the first and second non-wetting solder barrier metal layers comprise aluminum.

8. The thin film component of claim 1, wherein the thin film component is of a thickness in the range of 5 micrometers (um) to 20 um and a cross sectional dimension in the range of 50 um to 1000 um.

9. A method for fabricating an electronic device, the method comprising:
forming a plurality of thin film components on a wafer substrate;
cutting one or more of the thin film components from the wafer substrate;
extracting the one or more cut thin film components from the wafer substrate;
depositing the one or more extracted thin film components onto pads of a printed circuit board (PCB) assembly; and
performing a conductor reflow to electrically couple the one or more deposited thin film components to the pads of the PCB assembly.

10. The method of claim 9, wherein the thin film component comprises:
a release layer configured to provide release of the thin film component from the wafer substrate;
a layer of reflowable conductive material disposed on the release layer and configured to provide conductive material for the conductor reflow coupling to the PCB pad;
a first barrier metal layer disposed on the reflowable conductive material layer and configured to bond to the reflowable conductive material to protect the thin film component during the conductive material reflow;
a first non-wetting barrier metal layer disposed on the first barrier metal layer and configured to inhibit wicking of the reflowable conductive material around edges of the thin film component during the conductive material reflow;
a component function layer disposed on the first non-wetting barrier metal layer and configured to perform an electrical function of the thin film component;
a second non-wetting barrier metal layer disposed on the component function layer and configured to inhibit wicking of the reflowable conductive material around the edges of the thin film component during the conductive material reflow;
a second barrier metal layer disposed on the second non-wetting barrier metal layer and configured to bond to the reflowable conductive material to protect the thin film component during the conductive material reflow; and
a passivation metal layer disposed on the second barrier metal layer and configured to be consumed during the conductor reflow to protect the second barrier metal layer.

11. The method of claim 10, wherein the electrical function is a capacitor, and the component function layer is a dielectric.

12. The method of claim 10, wherein the electrical function is a resistor, and the component function layer is a resistive conductor.

13. The method of claim 10, wherein the electrical function is a diode, and the component function layer comprises an N-type semiconductor layer disposed on a P-type semiconductor layer.

14. The method of claim 10, wherein the electrical function is a thermocouple, and the component function layer comprises a first metal layer disposed on a second metal layer.

15. The method of claim 10, wherein the release layer and the passivation metal layer comprise gold, the first and second barrier metal layers comprise nickel, and the first and second non-wetting barrier metal layers comprise aluminum.

16. The method of claim 9, wherein the thin film component is of a thickness in the range of 5 micrometers (um) to 20 um and a cross sectional dimension in the range of 50 um to um, the wafer substrate is cylindrical with a diameter in the range of 7 inches to 9 inches, and the plurality of thin film components comprises 80000 to 90000 thin film components.

17. The method of claim 9, wherein the forming of the plurality of thin film components on the wafer substrate comprises performing a vapor deposition process and the cutting of the one or more of the thin film components from the wafer substrate comprises employing a laser to perform the cutting.

18. An electronic device comprising:
a printed circuit board (PCB) assembly comprising one or more solder pads;
one or more thin film components comprising a first side and a second side, the second side opposite the first side, wherein the first side of the thin film components are soldered to the solder pads of the PCB assembly; and
a circuit module comprising a ball grid array wherein the balls of the ball grid array are soldered to the second sides of the thin film components.

19. The electronic device of claim 18, wherein the thin film component comprises:
a release layer configured to provide release of the thin film component from a wafer substrate on which the thin film component was formed;
a solder metal layer disposed on the release layer and configured to provide solder for a solder reflow connection to the solder pads of the PCB assembly;
a first solder barrier metal layer disposed on the solder metal layer and configured to bond to the solder to protect the thin film component during the solder reflow;
a first non-wetting solder barrier metal layer disposed on the first solder barrier metal layer and configured to inhibit wicking of the solder around edges of the thin film component during the solder reflow;
a component function layer disposed on the first non-wetting solder barrier metal layer and configured to perform an electrical function of the thin film component;
a second non-wetting solder barrier metal layer disposed on the component function layer and configured to inhibit wicking of the solder around the edges of the thin film component during the solder reflow;
a second solder barrier metal layer disposed on the second non-wetting solder barrier metal layer and configured to bond to the solder to protect the thin film component during the solder reflow; and
a passivation metal layer disposed on the second solder barrier metal layer and configured to be consumed during soldering to protect the second solder barrier metal layer.

20. The electronic device of claim 19, wherein the electrical function is a capacitor, and the component function layer is a dielectric, or the electrical function is a resistor, and the component function layer is a resistive conductor, or the electrical function is a diode, and the component function layer comprises an N-type semiconductor layer disposed on a P-type semiconductor layer, or the electrical function is a thermocouple, and the component function layer comprises a first metal layer disposed on a second metal layer.
